(19) United States
(12) Patent Application Publication
(10) Pub. No.: US 2021/0291752 A1
(43) Pub. Date: Sep. 23, 2021

(54) METHOD FOR MANUFACTURING AUTOMOTIVE ORNAMENT

(71) Applicant: Hiroca Automotive Trim Corporation, Taoyuan City (TW)

(72) Inventors: Wu Chuan Chuang, Hsinchu City (TW); Shuming Lee, Hsinchu County (TW)

(73) Assignee: Hiroca Automotive Trim Corporation, Taoyuan City (TW)

(21) Appl. No.: 16/902,250

(22) Filed: Jun. 15, 2020

(30) Foreign Application Priority Data
Mar. 20, 2020 (CN) 202010201057.3
Mar. 20, 2020 (CN) 202010201071.3
Mar. 20, 2020 (CN) 202010201730.3

(51) Int. Cl. B60R 13/00; B60Q 1/56; B32B 7/12; B32B 37/10; B32B 37/12; B32B 7/06; B32B 37/26; B32B 38/06; B32B 38/10; B32B 38/00; B32B 38/18; B32B 7/025; B32B 27/36

(52) U.S. Cl. CPC B60R 13/005; B32B 2307/414; B32B 7/12; B32B 37/1018; B32B 37/1207; B32B 7/06; B32B 37/26; B32B 38/06; B32B 38/10; B32B 38/145; B32B 38/1858; B32B 7/025; B32B 27/365; B32B 2307/412; B32B 2037/1223; B32B 2037/268; B32B 2310/14; B32B 2305/34; B60Q 1/56

(57) ABSTRACT

A method for manufacturing an automotive ornament is provided, and the method includes following steps. A light-transmitting element is provided. At least one opening running through at least part of the light-transmitting element is formed. A sputtering layer is formed by a sputtering process using a sputtering device, where the sputtering layer is located in the at least one opening to form an ornament unit.

### CROSS-REFERENCE TO RELATED APPLICATION

This application claims the priority benefits of China patent application serial no. 202010201730.3, filed on Mar. 20, 2020, China patent application serial no. 202010201057.3, filed on Mar. 20, 2020, and China patent application serial no. 202010201071.3, filed on Mar. 20. 2020. The entirety of each of the above-mentioned patent applications is hereby incorporated by reference herein and made a part of this specification.

### BACKGROUND

### Technical Field

The disclosure relates to a method for manufacturing an ornament, and in particular, to a method for manufacturing an automotive ornament.

### Description of Related Art

An automobile has gradually become one of the common means of transportation for more and more families. The automobile has a variety of components, and automotive interiors and automotive exteriors are one of the common automotive components. Due to the complicated structure and the complicated manufacturing process of automotive ornaments in the related art, manufacturing costs of the automotive ornaments remain high. In addition, the automotive ornaments in the related art performs simple decorative functions and cannot meet actual requirements.

### SUMMARY

The disclosure provides a method for manufacturing an automotive ornament, which may greatly simplify a manufacturing process of the automotive ornament, reduce manufacturing costs, improve manufacturing efficiency, and improve decoration diversity of the automotive ornament by means of a light-transmitting element and a sputtering process.

According to an embodiment of the disclosure, a method for manufacturing an automotive ornament includes following steps. A light-transmitting element is provided. At least one opening running through at least part of the light-transmitting element is formed. A sputtering layer is formed by performing a sputtering process using a sputtering device, and the sputtering layer is located in the at least one opening to form an ornament unit.

In the method for manufacturing the automotive ornament according to an embodiment of the disclosure, the step of forming the light-transmitting element includes: providing a light-transmitting adhesive film, wherein the light-transmitting adhesive film includes a printing layer printed and coated by a printing device on a light-transmitting substrate A mask plastic layer is provided, and the mask plastic layer is adhered to the light-transmitting adhesive film, where the printing layer is sandwiched between the light-transmitting adhesive film and the mask plastic layer, and the at least one opening includes a first opening running through at least the mask plastic layer.

In the method for manufacturing the automotive ornament according to an embodiment of the disclosure, the step of forming the at least one opening includes: providing a laser engraving device that laser-engraves the light-transmitting element to form the at least one opening that runs through the at least part of the light-transmitting element.

The method for manufacturing the automotive ornament according to an embodiment of the disclosure further includes removing the mask plastic layer after the sputtering process is performed.

In the method for manufacturing the automotive ornament according to an embodiment of the disclosure, the at least one opening further includes a second opening that further runs through the printing layer.

The method for manufacturing the automotive ornament according to an embodiment of the disclosure further includes providing a vacuum-forming mold and putting the light-transmitting adhesive film in a vacuum-forming mold cavity of the vacuum-forming mold. The vacuum-forming mold vacuum-forms the light-transmitting adhesive film, and the printing layer is formed on the light-transmitting adhesive film after the light-transmitting adhesive film is vacuum-formed.

The method for manufacturing the automotive ornament according to an embodiment of the disclosure further includes providing a trimming unit that trims the light-transmitting adhesive film vacuum-formed by the vacuum forming mold, and the printing layer is formed on the light-transmitting adhesive film trimmed by the trimming unit.

In the method for manufacturing the automotive ornament according to an embodiment of the disclosure, the trimming unit includes a ring strip disposed rotationally, a driving member configured to drive the ring strip to rotate, and a cutter disposed on the ring strip and located in the vacuum-forming mold. The cutter is configured to trim the light-transmitting adhesive film vacuum-formed by the vacuum-forming mold and located in the vacuum-forming mold cavity.

In the method for manufacturing the automotive ornament according to an embodiment of the disclosure, the step of forming the at least one opening is before or after the step of forming the sputtering layer.

The method for manufacturing the automotive ornament according to an embodiment of the disclosure further includes providing an injection molding mold and putting the ornament unit in an injection molding mold cavity of the injection molding mold. The injection molding mold injection-molds a light-transmitting plastic member on the trim unit, and the light-transmitting plastic member covers the printing layer and the sputtering layer.

The method for manufacturing the automotive ornament according to an embodiment of the disclosure further includes: the light-transmitting element injection-molding a light-transmitting plastic member by using an injection molding mold. The sputtering layer is sputtered on the light-transmitting plastic member by using the sputtering device. The light-transmitting element at least partially run through by the at least one opening is disposed in the light-transmitting plastic member, and the light-transmitting element and the sputtering layer are located on one side of the light-transmitting plastic member. A light-emitting member is disposed on the other side of the light-transmitting plastic member opposite to the light-transmitting element and the sputtering layer, and light emitted by the light-emitting member is transmitted through the sputtering layer to display the sputtering layer.

In the method for manufacturing the automotive ornament according to an embodiment of the disclosure, the light-emitting member is adhered to the other side of the light-transmitting plastic member away from the sputtering layer by a double-sided tape or glue, or the light-emitting member is detachably fixed to the other side of the light-transmitting plastic member away from the sputtering layer by a fastener.

The method for manufacturing the automotive ornament according to an embodiment of the disclosure further includes providing a flexible circuit board, the light-emitting member is disposed on the flexible circuit board, the light-emitting member is electrically connected to the flexible circuit board, and the light-transmitting plastic member is coated on an outer side of the light-emitting member and an outer side of the flexible circuit board by injection molding.

In the method for manufacturing the automotive ornament according to an embodiment of the disclosure, the light-transmitting plastic member includes a blind slot and a clamping slot concavely disposed on a sidewall of the blind slot, and the blind slot is concavely formed on the other side of the light-transmitting plastic member away from the sputtering layer. The light-transmitting plastic member includes a conductive substrate housed in the blind slot, and the conductive substrate is provided with a clamping protrusion extending into the clamping slot. The light-emitting member is disposed on the conductive substrate, and the light-emitting member is electrically connected to an external power supply through the conductive substrate.

In the method for manufacturing the automotive ornament according to an embodiment of the disclosure, the sputtering layer is a linear strip, and the light-transmitting element is disposed around the sputtering layer.

In the method for manufacturing the automotive ornament according to an embodiment of the disclosure, the sputtering device sputters the sputtering layer in a vacuum state.

In the method for manufacturing the automotive ornament according to an embodiment of the disclosure, the light-transmitting plastic member is made of a transparent plastic material.

In the method for manufacturing the automotive ornament according to an embodiment of the disclosure, the light-transmitting adhesive film is made of a polymethyl methacrylate (PMMA) plastic material or a polyethylene terephthalate (PET) plastic material, or made by co-pressing a PMMA plastic layer and an acrylonitrile butadiene styrene (ABS) plastic layer or co-pressing a PMMA plastic layer and a polycarbonate (PC) plastic layer.

In the method for manufacturing the automotive ornament according to an embodiment of the disclosure, the light-transmitting adhesive film is made of a fully transparent plastic material or a translucent plastic material, or a semi-permeable oil layer is further formed between the light-transmitting adhesive film and the printing layer.

The method for manufacturing the automotive ornament according to an embodiment of the disclosure the printing layer further includes an anti-impact layer, and the anti-impact layer including transparent PC and astigmatism powder.

Based on the above, the method for manufacturing the automotive ornament provided in one or more embodiments of the disclosure greatly simplifies the manufacturing process of the automotive ornament, reduces the manufacturing costs, improves manufacturing efficiency, and improves decoration diversity of the automotive ornament by means of the light-transmitting element and the sputtering process.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a flow block diagram according to the disclosure.

FIG. 2 is a cross-sectional view of an automotive ornament according to the disclosure.

FIG. 3 is a cross-sectional view of another automotive ornament according to the disclosure.

FIG. 4 is a cross-sectional view of yet another automotive ornament according to the disclosure.

### DESCRIPTION OF THE EMBODIMENTS

Examples of exemplary embodiments of the disclosure are described in the accompanying drawings now in detail with reference to the exemplary embodiments of the disclosure. Where possible, identical reference numerals are used in the figures and descriptions to represent identical or similar parts.

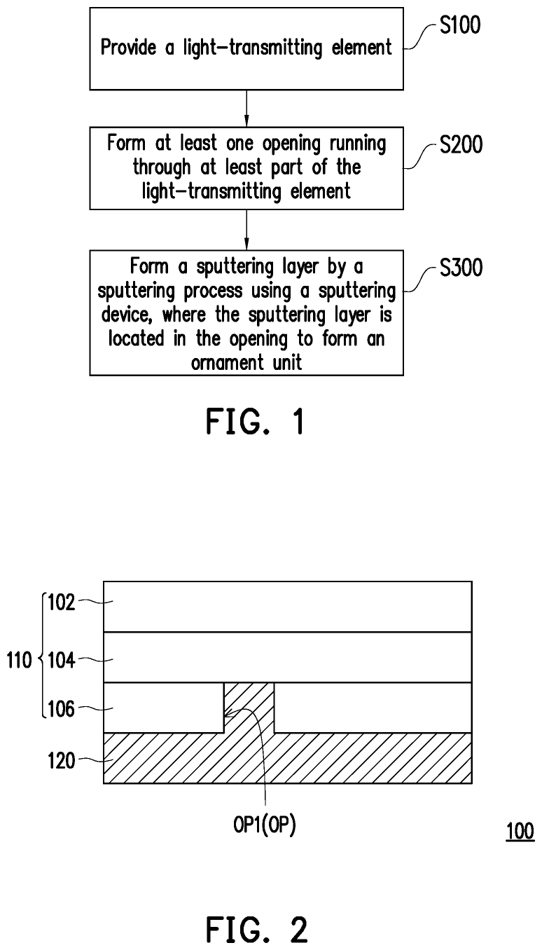

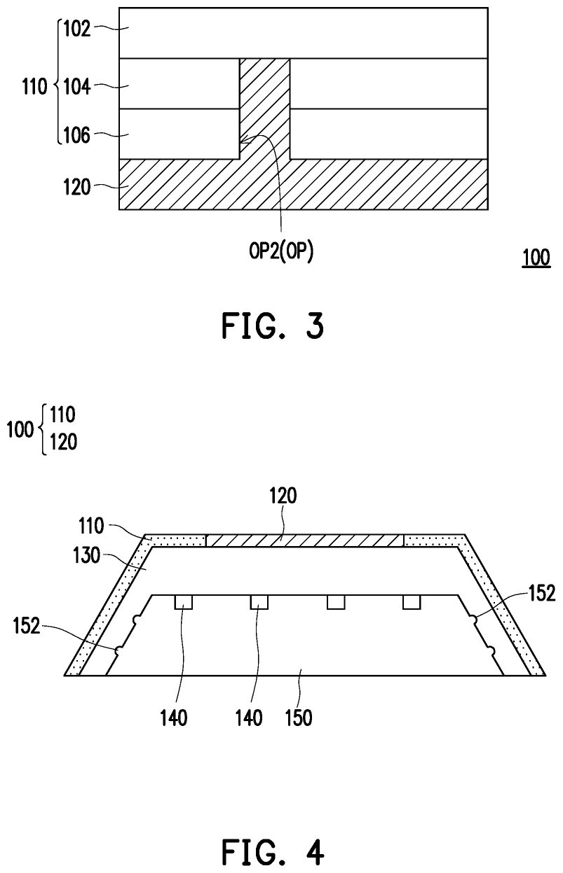

FIG. 1 is a flow block diagram according to the disclosure. FIG. 2 is a cross-sectional view of an automotive ornament according to the disclosure. FIG. 3 is a cross-sectional view of another automotive ornament according to the disclosure. FIG. 4 is a cross-sectional view of yet another automotive ornament according to the disclosure. Referring to FIG. 1 to FIG. 4 together, a method for manufacturing an automotive ornament according to the disclosure may include following steps.

In step S100, a light-transmitting element 110 is provided. In some embodiments, the light-transmitting element 110 may have a multi-layer structure. For example, the step of forming the light-transmitting element 110 may include providing a light-transmitting adhesive film 102, and the light-transmitting adhesive film 102 includes a printing layer 104 printed and coated on a light-transmitting substrate by a printing device. The light-transmitting adhesive film 102 may be made of a light-transmitting plastic material, and the light-transmitting adhesive film 102 may be shaped as a sheet, which should however not be construed as a limitation in the disclosure. The printing layer 104 may serve to decorate an automobile. The printing device may be a screen printing machine or the like. The printing layer 104 may be a color coating layer printed by the printing device on the light-transmitting adhesive film 102; for example, the printing layer is a yellow paint layer, a silver paint layer, or the like. In actual manufacturing, the printing layer 104 may be made of a light-transmitting coating. The printing layer 104 may also be a non-light-transmitting coating layer and may achieve a light transmission effect due to the small thickness of the non-light-transmitting coating layer. A mask plastic layer 106 is provided. The mask plastic layer 106 may be called MASK PET for short. PET is polyethylene terephthalate. The mask plastic layer 106 is adhered to the light-transmitting adhesive film 102, the mask plastic layer 106 covers the printing layer 104, and the printing layer 104 is sandwiched between the light-transmitting adhesive film 102 and the mask plastic layer 106.

In some embodiments, the light-transmitting adhesive film 102 may be made of a transparent plastic material, where the transparent plastic material may be a fully transparent plastic material or a translucent plastic material. The good light transmission performance of the light-transmitting plastic material may assist in improving light-transmitting decoration efficiency of the automotive ornament for an automobile.

In some embodiments, the light-transmitting adhesive film 102 may be made of a PMMA plastic material. The PMMA plastic material is also called acryl, acrylic, or perspex.

In some embodiments, the light-transmitting adhesive film 102 may be made of a PET plastic material, and PET is polyethylene terephthalate.

In some embodiments, the light-transmitting adhesive film 102 is made by co-pressing a PMMA plastic layer and an ABS plastic layer. The PMMA plastic layer is made of a PMMA plastic material, and the ABS plastic layer is made of an ABS plastic material.

In some embodiments, the light-transmitting adhesive film is made by co-pressing a PMMA plastic layer and a PC plastic layer. The PC plastic layer is made of a PC plastic material.

In some embodiments, a semi-permeable oil layer (not shown) is further formed between the light-transmitting adhesive film 102 and the printing layer 104, which should however not be construed as a limitation in the disclosure.

In step S200, at least one opening OP running through at least part of the light-transmitting element 110 is formed. In some embodiments, the step of forming the at least one opening OP may include providing a laser engraving device that laser-engraves the light-transmitting element 110 to form the at least one opening OP that runs through at least part of the light-transmitting element 110. The opening OP may be shaped in various forms; for example, the opening may be a curve, a plant pattern, an animal pattern, or the like. With the characteristics of laser engraving, diversified engraving and precision engraving may be achieved to improve manufacturing efficiency and yield of the opening OP.

In some embodiments, as shown in FIG. 2, the opening OP may include a first opening OP1 running through at least the mask plastic layer 106, which should however not be construed as a limitation in the disclosure. In another embodiment, as shown in FIG. 3, the opening OP may further include a second opening OP2 further running through the printing layer 104.

In step S300, a sputtering layer 120 is formed by performing a sputtering process using a sputtering device, where the sputtering layer 120 is located in the opening OP to form an ornament unit 100. The sputtering device may sputter the sputtering layer 120 at the opening OP. The sputtering layer 120 is sputtered by the sputtering device, which, compared with conventional processes such as electroplating and vacuum-plating, can facilitate local coating and save processing and manufacturing costs. Moreover, the sputtering process greatly reduces the thickness of the sputtering layer 120, ensures a good light transmission effect of the sputtering layer 120, and improves a light transmission decoration performance of the automotive ornament. In addition, when the light-transmitting element 110 includes the mask plastic layer 106, during the sputtering process by the sputtering device, sputtering outside the opening can be prevented due to the coverage effect of the mask plastic layer 106, thus improving the sputtering yield. The sputtering layer 120 may be a silver layer, a white layer, or the like.

In some embodiments, after the sputtering process is performed by the sputtering device, the mask plastic layer 106may be removed, which should however not be construed as a limitation in the disclosure.

In some embodiments, in the method for manufacturing an automotive ornament according to the disclosure, the printing device prints and coats a printing layer 104 on the light-transmitting adhesive film 102, a mask plastic layer 106 is adhered to the light-transmitting adhesive film 102, the mask plastic layer 106 covers the light-transmitting printing layer 104, the mask plastic layer 106 is laser-engraved using a laser engraving device to form an opening running through the mask plastic layer 106, a sputtering layer 120 is sputtered at the opening by using a sputtering device, and after the sputtering process is by the sputtering device, the mask plastic layer 106 is removed, thus forming the ornament unit 100.

On the other hand, in the actual manufacturing process, the sputtering layer 120 located in the first opening OP1 (running through the mask plastic layer 106) may be a first sputtering layer, and the sputtering layer located in the second opening OP2 (running through the mask plastic layer 106 and the printing layer 104) may be a second sputtering layer. In some embodiments, the first sputtering layer and the second sputtering layer may exist individually, which should however not be construed as a limitation in the disclosure. The first sputtering layer and the second sputtering layer may also co-exist. When the first sputtering layer and the second sputtering layer co-exist, a light-emitting member may be added; as such, after light emitted by the light-emitting member is transmitted out of the light-transmitting adhesive film by the first sputtering layer and the second sputtering layer, light transmission of the entire automotive ornament is in a state of light and shade contrast. That is, the light transmitted out of the light-transmitting adhesive film by the first sputtering layer is semi-bright, and the light transmitted out of the light-transmitting adhesive film by the second sputtering layer is fully bright, thereby further improving the decoration performance of the automotive ornament.

After the automotive ornament is installed on an automobile, the automobile is decorated by the printing layer 104 during the day. At night, light emitted by the light-emitting member of the automobile may be transmitted out of the light-transmitting adhesive film 102 by the sputtering layer 120 to achieve a decoration effect for the automobile, which should however not be construed as a limitation in the disclosure.

In some embodiments, the method for manufacturing an automotive ornament may further include following steps.

A vacuum-forming mold (not shown) is provided, the light-transmitting adhesive film 102 is put in a vacuum-forming mold cavity of the vacuum-forming mold, the light-transmitting adhesive film 102 in the vacuum-forming mold cavity is heated by the vacuum-forming mold, and after the light-transmitting adhesive film 102 is softened by the heat, the light-transmitting adhesive film is vacuum-formed by the vacuum-forming mold, so that the light-transmitting adhesive film 102 is quickly shaped as required, and the printing device prints and coats the printing layer 104 on the light-transmitting adhesive film 102 vacuum-formed by the vacuum-forming mold. Compared with the light-transmitting adhesive film 102 manufactured through bending and cutting processes, the light-transmitting adhesive film 102 may have the improved molding efficiency through the vacuum-forming process, thus improving manufacturing efficiency of the automotive ornament.

In some embodiments, a trimming unit (not shown) may also be provided. The trimming unit may trim residual materials on the sides and corners of the light-transmitting adhesive film 102 vacuum-formed by the vacuum-forming mold, and the printing device prints and coats the printing layer 104 on the light-transmitting adhesive film 102 trimmed by the trimming unit. Owing to the removal of the residual materials on the sides and corners of the light-transmitting adhesive film 102 by means of the trimming unit, the molding yield and the molding efficiency of the light-transmitting adhesive film 102 may be further enhanced.

In some embodiments, the trimming unit may include a ring strip disposed rotationally, a driving member configured to drive the ring strip to rotate, and a cutter disposed on the ring strip and located in the vacuum-forming mold. According to actual requirements, the ring strip may be a steel wire rope, the trimming unit is provided with a plurality of rotational wheel bodies, the ring strip is sleeved on an outer side of the wheel body, and the driving member is a motor driving the wheel bodies to rotate. Certainly, there may be a plurality of cutters. After the light-transmitting adhesive film 102 is vacuum-formed in the vacuum-forming mold cavity, the driving member drives the cutter to move by the ring strip, and the light-transmitting adhesive film vacuum-formed by the vacuum-forming mold and located in the vacuum-forming mold cavity is trimmed by using the moving cutter. Compared with the manner of moving the light-transmitting adhesive film out of the vacuum-forming mold for secondary positioning before trimming, positioning the light-transmitting adhesive film 102 by the vacuum-forming mold cavity improves trimming yield.

In some embodiments, the method for manufacturing the automotive ornament may further include following steps.

An injection molding mold (not shown) is provided, the light-transmitting element 110 is put in an injection molding mold cavity of the injection molding mold, and injection-molding, by the injection molding mold, is performed on a light-transmitting plastic member on the ornament unit 100. The sputtering layer 120 is then formed by performing a sputtering process on the light-transmitting plastic member by a sputtering device.

The light-transmitting plastic member is connected and secured to the ornament unit 100 by injection molding, which improves manufacturing efficiency of the automotive ornament and increases a connection between the light-transmitting plastic member and the ornament unit, ensuring that the two are firmly connected together, which should however not be construed as a limitation in the disclosure.

In some embodiments, the light-transmitting plastic member may cover the printing layer 104 and the sputtering layer 120 in the light-transmitting element 110.

In some embodiments, a light-emitting member (such as an LED) corresponding to the sputtering layer 120 may be preset in the injection molding mold cavity of the injection molding mold, and the light-emitting member may be connected and secured to the ornament unit 100 by the light-transmitting plastic member. Certainly, the light-transmitting plastic member may be made of a light-transmitting plastic material, the light-emitting member is mounted to a side of the light-transmitting plastic member away from the ornament unit 100, and light emitted by the light-emitting member passes through the light-transmitting plastic member and the sputtering layer 120 and is emitted through the light-transmitting adhesive film 102.

In some embodiments, the printing layer 104 may be further includes an anti-impact layer (not shown). When a melted plastic material of the injection molding mold is injected into the injection molding mold cavity and hits the printing layer 104, decorative patterns or colors of the printing layer 104 is protected from being damaged due to the anti-impact effect of the anti-impact layer. In addition, the printing layer 104 may have light-transmitting characters or patterns. Therefore, when there is no light source, decoration may be made by painting colors, and when there is an external light source, light may pass through the characters or patterns to display the characters or patterns, which should however not be construed as a limitation in the disclosure.

In some embodiments, the anti-impact layer may cover the opening, which should however not be construed as a limitation in the disclosure. In some other embodiments, the anti-impact layer may be laser-engraved by a laser-engraving device to form another opening, which runs through the anti-impact layer and may communicate with the above opening.

In some embodiments, the anti-impact layer may include transparent PC and astigmatism powder, and thus brightness variations may be improved, which should however not be construed as a limitation in the disclosure.

It should be noted that the step of forming the at least one opening OP as provided in the above embodiment is before the step of forming the sputtering layer 120, and the ornament unit 100 is formed before the light-transmitting plastic member is disposed on the ornament unit 100; however, a sequence of forming the opening OP of the light-transmitting element 110, the sputtering layer 120, and the light-transmitting plastic member is not limited in the disclosure.

In some embodiments, the step of forming the at least one opening OP may be after the step of forming the sputtering layer 120, and the light-transmitting plastic member may be provided before the ornament unit 100 is formed on the light-transmitting plastic member, as long as the at least one opening OP running through at least part of the light-transmitting element 110 is formed. The sputtering layer 120 is formed by performing a sputtering process using a sputtering device, where the sputtering layer 120 is located in the opening OP to form the ornament unit 100. These all fall within the protection scope of the disclosure. For example, as shown in FIG. 4, the step of forming the light-transmitting plastic member 130 may include providing a light-transmitting plastic material, heating the light-transmitting plastic material to a melted state, injecting the light-transmitting plastic material in the melted state in an injection molding mold, and injection-molding, by the injection molding mold, the melted light-transmitting plastic into the light-transmitting plastic member 130. Next, the sputtering layer 120 is formed by performing a sputtering process on the light-transmitting plastic member 130 with use of a sputtering device. Then, the light-transmitting element 110 run thorough by the at least one opening OP is disposed on the light-transmitting plastic member 130 to form the ornament unit 100 constituted by the sputtering layer 120 and the light-transmitting element 110 on the light-transmitting plastic member 130. The ornament unit 100 is adhered to the light-transmitting plastic member 130, and the ornament unit 100 is on a side of the light-transmitting plastic member 130.

In some embodiments, the light-emitting member 140 may also be disposed on the light-transmitting plastic member 130, and light emitted by the light-emitting member 140 is transmitted through the sputtering layer 120 to display the sputtering layer 120.

In actual use, the automotive ornament is mounted on a frame of the automobile through the light-transmitting plastic member 130, and the automobile is decorated by the ornament unit 100 during the day; at night or when the light is slim, the light emitted by the light-emitting member 140 is transmitted through the sputtering layer 120 to display the sputtering layer 120, and the automobile is decorated by the sputtering layer 120, which simplifies the manufacturing process of the automotive ornament, improves manufacturing efficiency, reduces manufacturing costs, and improves diversity of the automotive ornament.

In some embodiments, the sputtering device may sputter the sputtering layer 120 on the light-transmitting plastic member 130 in a vacuum state, which reduces possible interference of an external material with the sputtering layer 120 and improves uniformity and sputtering yield of the spluttering layer 120.

In some embodiments, the light-emitting member 140 may be adhered to a side of the light-transmitting plastic member away from the sputtering layer 120 by a double-sided tape or glue. According to actual requirements, the light-emitting member 140 may be a light-emitting bead (such as an LED), a light-emitting strip, a light-emitting band, or the like, and adhering the light-emitting member 140 to the light-transmitting plastic member 130 by a double-sided tape or glue simplifies a mounting mechanism between the light-emitting member 140 and the light-transmitting plastic member 130.

In some other embodiments, the light-emitting member 140 may be detachably fixed to a side of the light-transmitting plastic member away from the sputtering layer by a fastener (not shown). According to actual requirements, the fastener may be a screw, a rivet, a bolt, or the like. The light-emitting member is fixed to the light-transmitting plastic member by means of the fastener, which increases a connection strength between the light-emitting member 140 and the light-transmitting plastic member 130 and prevents the light-emitting member 140 from falling from the light-transmitting plastic member 130.

In yet another embodiment, the light-transmitting plastic member 130 may be coated on an outer side of the light-emitting member 140 by injection molding. In actual use, the light-emitting member 140 is put in the injection molding mold cavity of the injection molding mold, the injection molding mold injects the melted light-transmitting plastic material into the injection molding mold cavity, the melted light-transmitting plastic material injected into the injection molding mold cavity wraps the light-emitting member, and after the melted light-transmitting plastic material is cooled and cured, it becomes the light-transmitting plastic member 130. Coating the light-transmitting plastic member 130 on the outer side of the light-emitting member 140 by injection molding, on the one hand, improves the mounting efficiency between the light-emitting member 140 and the light-transmitting plastic member 130, and on the other hand, prevents the light-emitting member 140 from falling from the light-transmitting plastic member 130.

In some embodiments, a flexible circuit board may be further formed. The light-emitting member may be mounted on the flexible circuit board. The light-emitting member is electrically connected to the flexible circuit board, and the light-transmitting plastic member may be coated on an outer side of the light-emitting member and an outer side of the flexible circuit board by injection molding.

In some embodiments, the light-transmitting plastic member 130 may be made of a transparent plastic material, for example, the light-transmitting plastic member is made of a transparent PC plastic material, a transparent PET plastic material, a transparent ABS plastic material, or the like, which reduces a blocking effect of the light-transmitting plastic member 130 on the light emitted by the light-emitting member 140 and improves brightness of the light of the light-emitting member 140 transmitted out of the sputtering layer 120.

In some embodiments, the light-transmitting plastic member 130 may include a blind slot and a clamping slot concavely disposed on a sidewall of the blind slot, and the blind slot is concavely formed on a side of the light-transmitting plastic member away from the sputtering layer. The light-transmitting plastic member includes a conductive substrate 150 housed in the blind slot; for example, the conductive substrate 150 is a printed circuit board. The conductive substrate 150 is provided with a clamping protrusion 152 extending into the clamping slot, the light-emitting member 140 is disposed on the conductive substrate 150, and the light-emitting member 140 may be electrically connected to an external power supply through the conductive substrate 150.

In some embodiments, the sputtering layer 120 may be a linear strip, and the light-transmitting element 110 may be disposed around the sputtering layer 120.

In actual use, the light-emitting member 140 may be first welded and fixed to the conductive substrate 150, the conductive substrate 150 is, along with the light-emitting member 140, mounted on the light-transmitting plastic member 130, and with the blind slot, the light-transmitting plastic member 130 and the frame of the automobile are prevented from damaging the light-emitting member 140. An inner slot wall of the clamping slot blocks collision with the clamping protrusion 152, so that the conductive substrate 150 is quickly clamped onto the light-transmitting plastic member 130, and on the other hand, the mounting process of fixing the conductive substrate 150 and the light-transmitting plastic member 130 may be simplified.

To sum up, the method for manufacturing the automotive ornament according to one or more embodiments of the disclosure greatly simplifies the manufacturing process of the automotive ornament, reduces the manufacturing costs, improves the manufacturing efficiency, and improves decoration diversity of the automotive ornament by means of the light-transmitting element and the sputtering process.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A method for manufacturing an automotive ornament, the method comprising:
providing a light-transmitting element;
forming at least one opening running through at least part of the light-transmitting element; and
forming a sputtering layer by performing a sputtering process using a sputtering device, wherein the sputtering layer is located in the at least one opening to form an ornament unit.

2. The method according to claim 1, wherein the step of forming the light-transmitting element comprises:
providing a light-transmitting adhesive film, wherein the light-transmitting adhesive film comprises a printing layer printed and coated by a printing device on a light-transmitting substrate; and
providing a mask plastic layer, and adhering the mask plastic layer to the light-transmitting adhesive film, wherein the printing layer is sandwiched between the light-transmitting adhesive film and the mask plastic layer, and the at least one opening comprises a first opening running through at least the mask plastic layer.

3. The method according to claim 1, wherein the step of forming the at least one opening comprises:
providing a laser engraving device, the laser engraving device laser-engraving the light-transmitting element to form the at least one opening that runs through the at least part of the light-transmitting element.

4. The method according to claim 2, further comprising removing the mask plastic layer after performing the sputtering process.

5. The method according to claim 2, wherein the at least one opening further comprises a second opening that further runs through the printing layer.

6. The method according to claim 2, further comprising:
providing a vacuum-forming mold, and putting the light-transmitting adhesive film in a vacuum-forming mold cavity of the vacuum-forming mold, wherein the vacuum-forming mold vacuum-forms the light-transmitting adhesive film in the vacuum-forming mold cavity, and the printing layer is formed on the light-transmitting adhesive film after the light-transmitting adhesive film is vacuum-formed.

7. The method according to claim 6, further comprising:
providing a trimming unit, the trimming unit trimming the light-transmitting adhesive film vacuum-formed by the vacuum-forming mold, the printing layer being formed on the light-transmitting adhesive film after the light-transmitting adhesive film is trimmed by the trimming unit.

8. The method according to claim 7, wherein the trimming unit comprises a ring strip disposed rotationally, a driving member configured to drive the ring strip to rotate, and a cutter disposed on the ring strip and located in the vacuum-forming mold, the cutter being configured to trim the light-transmitting adhesive film vacuum-formed by the vacuum-forming mold and located in the vacuum-forming mold cavity.

9. The method according to claim 1, wherein the step of forming the at least one opening is before or after the step of forming the sputtering layer.

10. The method according to claim 2, further comprising:
providing an injection molding mold, and putting the ornament unit in an injection molding mold cavity of the injection molding mold, the injection molding mold injection-molding a light-transmitting plastic member on the ornament unit, the light-transmitting plastic member covering the printing layer and the sputtering layer.

11. The method according to claim 1, further comprising:
the light-transmitting element injection-molding a light-transmitting plastic member by using an injection molding mold;
sputtering the sputtering layer on the light-transmitting plastic member by using the sputtering device;
disposing the light-transmitting element at least partially run through by the at least one opening at the light-transmitting plastic member, the light-transmitting element and the sputtering layer being located on one side of the light-transmitting plastic member; and
disposing a light-emitting member on the other side of the light-transmitting plastic member opposite to the light-transmitting element and the sputtering layer, light emitted by the light-emitting member being transmitted through the sputtering layer to display the sputtering layer.

12. The method according to claim 11, wherein
the light-emitting member is adhered to the other side of the light-transmitting plastic member away from the sputtering layer by a double-sided tape or glue; or
the light-emitting member is detachably fixed to the other side of the light-transmitting plastic member away from the sputtering layer by a fastener.

13. The method according to claim 12, further comprising providing a flexible circuit board, the light-emitting member being disposed on and electrically connected to the flexible circuit board, the light-transmitting plastic member being coated on an outer side of the light-emitting member and an outer side of the flexible circuit board by injection molding.

14. The method according to claim 11, wherein the light-transmitting plastic member comprises a blind slot and a clamping slot concavely disposed on a sidewall of the blind slot, the blind slot is concavely formed on the other side of the light-transmitting plastic member away from the sputtering layer, the light-transmitting plastic member comprises a conductive substrate housed in the blind slot, the conductive substrate is provided with a clamping protrusion extending into the clamping slot, the light-emitting member is disposed on the conductive substrate, and the light-emitting member is electrically connected to an external power supply through the conductive substrate.

15. The method according to claim 1, wherein the sputtering layer is a linear strip, and the light-transmitting element is disposed around the sputtering layer.

16. The method according to claim 1, wherein the sputtering device sputters the sputtering layer in a vacuum state.

17. The method according to claim 2, wherein
the light-transmitting plastic member is made of a transparent plastic material.

18. The method according to claim 2, wherein the light-transmitting adhesive film is made of a polymethyl methacrylate plastic material or a polyethylene terephthalate plastic material, or made by co-pressing a polymethyl methacrylate plastic layer and an acrylonitrile butadiene styrene plastic layer or co-pressing a polymethyl methacrylate plastic layer and a polycarbonate plastic layer.

19. The method according to claim 2, wherein
the light-transmitting adhesive film is made of a fully transparent plastic material or a translucent plastic material; or
a semi-permeable oil layer is further formed between the light-transmitting adhesive film and the printing layer.

20. The method according to claim 1, further comprising providing an anti-impact layer on the printing layer, the anti-impact layer comprising transparent polycarbonate and astigmatism powder.
